(19) United States
(12) Patent Application Publication
(10) Pub. No.: US 2025/0246561 A1
(43) Pub. Date: Jul. 31, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Feng-Chien Hsieh, Pingtung (TW); Yun-Wei Cheng, Taipei (TW); Wei-Li Hu, Tainan (TW); Kuo-Cheng Lee, Tainan (TW); Cheng-Ming Wu, Tainan (TW)

(73) Assignee: Taiwan Semiconductor Manufacturing Company, Ltd., Hsinchu (TW)

(21) Appl. No.: 18/424,135

(22) Filed: Jan. 26, 2024

(51) Int. Cl. H01L 23/00; H01L 23/522

(52) U.S. Cl. CPC H01L 24/03; H01L 23/5226; H01L 24/05; H01L 2224/0311; H01L 2224/05558; H01L 2224/05624; H01L 2224/05647

(57) ABSTRACT

A fabrication method includes: providing a substrate having a front side surface, a back side surface, and a contact pad region; providing an interconnect structure embedded in an interlayer dielectric (ILD) layer below the front side surface of the substrate; forming a first contact pad opening in the contact pad region that extends from above the back side surface through the substrate to an interior area of the ILD layer below the front side surface; forming a contact pad that extends from the first contact pad opening to the interconnect structure; forming an oxide layer over the contact pad; and forming a scribe line pad opening through the oxide layer to the contact pad.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts a cross-sectional view of an example portion of a semiconductor device, according to some embodiments.

FIG. 2 is a flow diagram of an example method for fabricating a CMOS image sensor (CIS) device, according to some embodiments.

FIGS. 3A-31, depict cross-sectional views of a CIS device at various stages of its fabrication process, according to some embodiments.

FIG. 4 is a cross-sectional schematic diagram that illustrates an example anisotropic etching wall that can be achieved for a scribe line pad opening, according to some embodiments.

FIG. 5 depicts a schematic cross-sectional view of an example portion of an example CIS device, according to some embodiments.

FIG. 6 depicts a schematic cross-sectional view of an example portion of an example CIS device, according to some embodiments.

FIG. 7 depicts a schematic cross-sectional view of an example portion of an example CIS device, according to some embodiments.

FIG. 8 depicts a schematic cross-sectional view of an example portion of an example CIS device, according to some embodiments.

FIG. 9 depicts a schematic cross-sectional view of an example portion of an example CIS device, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

Semiconductor image sensors are used to sense incoming visible or non-visible radiation, such as visible light, infrared light, etc. Complementary metal-oxide-semiconductor (CMOS) image sensors (CIS) and charge-coupled device (CCD) sensors are used in various applications, such as digital still cameras, mobile phones, tablets, goggles, etc. These image sensors utilize an array of pixels that absorb (e.g., sense) the incoming radiation and convert it into electrical signals. An example of an image sensor is a backside illuminated (BSI) image sensor, which detects radiation from a “backside” of a substrate of the BSI image sensor.

A backside illumination (BSI) image sensor is a type of CIS device. A BSI image sensor includes a pixel region with an array of pixels or radiation-sensing regions formed on a substrate (e.g., a semiconductor substrate). The terms “radiation-sensing regions” and “pixels” may be used interchangeably throughout this disclosure. The pixels are configured to convert photons from the incident radiation to an electrical signal. The electrical signal is subsequently distributed to processing components attached to the BSI image sensor. For this reason, the pixel region overlies an interconnect structure in a multilevel metallization layer configured to distribute the electrical signal generated within the pixels to appropriate processing components. The multilevel metallization layer is formed on a first surface of the substrate referred to as the “front side” surface of the substrate. The pixel region is formed on a second surface of the substrate that is opposite to the front side surface of the substrate. This second surface of the substrate is referred to herein as the “backside” surface of the substrate. The pixel region includes a grid structure that provide optical isolation between adjacent pixels. Further, the pixel region includes color filtering layers. The material of color filtering layers can be selected such that light with a desired wavelength passes through the color filtering layers, while light with other wavelengths is absorbed by the color filtering layers.

The components of the BSI image sensor (e.g., pixels, transistors, capacitors, memory structures, or other chips attached to the BSI image senor) can be electrically coupled to external devices (e.g., an external circuitry) through wire connectors attached to pad structures formed on the back side surface of the substrate. To achieve this, the pad structures of the BSI image sensor extends from the back side surface of the substrate to the front side surface of the substrate and electrically connect to the interconnect structure in the multilevel metallization layer of the BSI image sensor. Accordingly, the interconnect structure in the multilevel metallization layer, which provides electrical signal connection to the BSI image sensor, can be electrically connected to an external device or circuit through the pad structures. The pad structures can be disposed at the periphery of the BSI image sensor around the pixel region.

A challenge with BSI image sensors is achieving high device reliability. The device reliability of BSI image sensors can be negatively impacted by stress build-up during fabrication operations. In a BSI image sensor, the pad structure may be constructed by forming a first cavity portion of a contact pad opening that terminates at a shallow trench isolation (STI) region in the substrate followed by forming a second cavity portion of the contact pad opening through the substrate and an interlayer dielectric (ILD) layer to the interconnect structure. Silicon (Si) dislocation in the STI region of the substrate due to stress buildup resulting from chemical mechanical polishing (CMP) operations during pixel construction can result and cause a crystal defect, which negatively impacts fabrication yield.

In accordance with some embodiments of the present disclosure, the first cavity portion of the contact pad opening extends to the ILD layer and does not terminate in an STI region of the substrate. As a result, the STI region is not needed and a crystal defect due to Si dislocation in the STI region can be avoided. Plural intermediate stages of manufacturing an image sensor device are illustrated. Variations of the embodiments are also discussed. Throughout the various views and illustrative embodiments, like reference numbers are used to designate like elements.

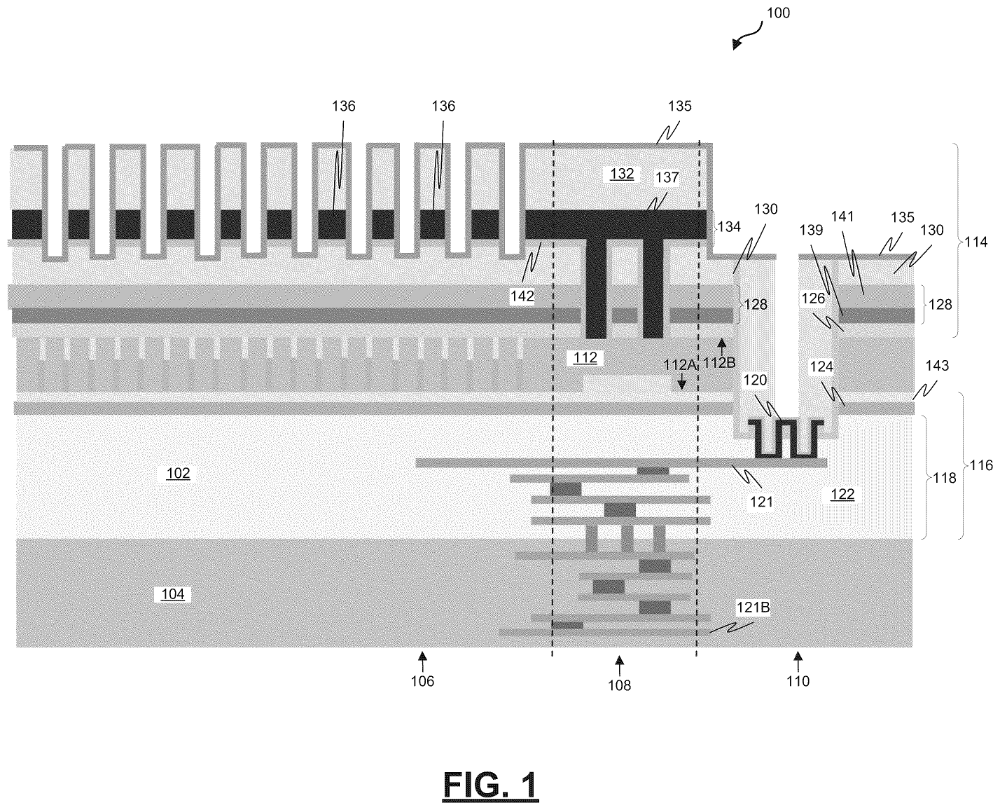

FIG. 1 depicts a schematic cross-sectional view of an example portion of an example CIS device 100. The example CIS device 100 includes a CIS system-on-a-chip (SOC) 102 and a carrier substrate, such as an application specific integrated circuit (ASIC) 104. The example CIS device 100, including the CIS SOC 102 and the ASIC 104, has a plurality of regions including a pixel array region 106, a periphery region 108 (such as a black level correction (BLC) region) laterally surrounding the pixel array region 106, and a contact pad (PAD) region 110. The example CIS device 100 may further include other regions such as, for example, an alignment region such as a scribe-line primary mark (SPM) region, which are not explicitly illustrated, since their inclusion is not necessary for understanding various embodiments described herein.

The example CIS SOC 102 includes a substrate 112 with a front side surface 112A and a back side surface 112B, a first stack of layers 114 disposed on the back side surface 112B, a second stack of layers 116 disposed on the front side surface 112A, a multi-level metallization layer 118 disposed within the second stack of layers 116, and a contact pad structure 120 disposed within the PAD region 110. The contact pad structure 120 is an input/output (I/O) port of the CIS device 100 and includes a conductive layer that is electrically coupled to an interconnect structure 121 of the multi-level metallization layer 118, which is embedded in an ILD layer 122 of the multi-level metallization layer 118. The example CIS SOC 102 can include additional components, such as micro-lenses on the first stack of layers 114, a solder bump on the contact pad structure 120, metal wirings, active and/or passive devices, insulating layers, etch stop layers, and doped regions that are not shown for simplicity. The example first stack of layers 114 includes a first dielectric layer 126 (e.g., an oxide layer such as ALO, an oxynitride layer, or other suitable materials with color filtering properties), an ARC layer 128, a first oxide layer 130, a second oxide layer 132 (e.g., an oxide film, such as undoped silicon glass (USG) or another suitable dielectric material), a metal layer 134, and a third oxide layer 135. The example second stack of layers 116 include a fourth oxide layer 143, a contact etch stop layer 124 (CESL), and the multi-level metallization layer 118.

The substrate 112 may be a semiconductor substrate, such as a bulk semiconductor, a semiconductor-on-insulator (SOI) substrate, a semiconductor wafer, or the like, which may be doped (e.g., with a p-type or an n-type dopant) or undoped. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AllnAs, AlGaAs, GalnAs, GalnP, and/or GalnAsP; or combinations thereof.

The interconnect structure 121 provides routing and electrical connections between device elements formed in and/or over the substrate 112. The interconnect structure 121 may include one or more conductive features, which in this example include metal lines and/or vias formed therein in multi-level metallization layer 118. The conductive features may be electrically connected to active and/or passive devices of the substrate 112 by contacts (not shown in the figures). In some embodiments, the interconnect structure 121 may be formed using a single and/or a dual damascene process, a VIA-first process, or a metal-first process.

Conductive material for the metal lines and/or vias may be formed from conductive material, such as copper (Cu), aluminum (Al), tungsten (W), nickel, cobalt, silver, combinations thereof, or other applicable materials, and may be formed using an electro-chemical plating process, chemical vapor deposition (CVD), atomic layer deposition (ALD), physical vapor deposition (PVD), the like, or a combination thereof. After formation of the conductive material, excess conductive material may be removed using, for example, a planarization process such as chemical mechanical polishing (CMP). The interconnect structure 121 shown in FIG. 1 is merely for illustrative purposes. The interconnect structure 121 may include other configurations and may include one or more metal lines and intermetal dielectric (IMD) layers.

The example pixel array region 106 includes the metal layer 134 having a metal grid structure with grid lines 136 that isolates pixels from each other. The example pixel array region 106 is configured to receive incident radiation beams, which are converted to an electrical signal through the first stack of layers 114 in the pixel array region 106. The electrical signal is distributed by the contact pad structure 120 and the interconnect structure 121 to the ASIC 104 or an external circuit. The ASIC 104 can be bonded to the multi-level metallization layer 118 by molecular forces—a technique known as direct bonding or optical fusion bonding—or by other bonding techniques known in the art, such as metal diffusion or anodic bonding. In some embodiments, the ASIC 104 can include materials similar to substrate 112 or can include a glass substrate. The ASIC 104 can include active devices (e.g., transistor structures) to form logic and memory circuits in the ASIC. Electrical connections between active devices in the ASIC 104 and the first stack of layers 114 are provided by an interconnect structure 121B in the ASIC 104.

The periphery region 108 can include a grounded metal shield 137 in the metal layer 134 that provides optical shielding to active devices (not shown) in the periphery region 108 to keep the active devices optically dark. The active devices in the periphery region 108 can be reference pixels that are used to establish a baseline of an intensity of light for the CIS SOC 102. The PAD region 110 can include one or more conductive bonding pads or solder bumps (not shown) on the contact pad structure 120 through which electrical connections between the CIS device 100 and external circuit can be established.

The first stack of layers 114 can include a first dielectric layer 126 on the back side surface 112B, an ARC layer 128 disposed on the first dielectric layer 126 to reduce reflection of incident light, a first oxide layer 130 disposed on the ARC layer 128, a metal layer 134 disposed on the first oxide layer 130, a second oxide layer 132 disposed on metal layer 134, and a third oxide layer 135 disposed on the second oxide layer 132. In some embodiments, the ARC layer 128 can include a first ARC layer 139 and a second ARC layer 141. In various embodiments, the first ARC layer 139 includes a high-k dielectric material, such as hafnium oxide (HfO₂). In various embodiments, the second ARC layer 141 includes a high-k dielectric material, such as, such as tantalum oxide (Ta₂O₅). ‘In other embodiments, the ARC layer 128 can include a high-k dielectric material, such as titanium oxide (TiO₂), hafnium zirconium oxide (HfZrO), hafnium silicate (HfSiO₄), zirconium oxide (ZrO₂), and zirconium silicate (ZrSiO₂) or other suitable high-k dielectric materials. In various embodiments, the third oxide layer 135 can include a plasma-enhanced oxide (PEOX) layer formed using plasma enhanced CVD process with a tetraethyl oxysilane (PETEOS) precursor. In some embodiments, the metal layer 134 includes a titanium nitride (TiN) layer 142. In some embodiments, the metal layer 134 includes tungsten (W) or other suitable metallic materials formed over the TIN layer 142.

In an embodiment, the substrate 112 is formed from Si having a thickness of about 3 micrometers, the first dielectric layer 126 is formed from an aluminum oxide (AlO) having a thickness of about 40 Angstroms (A), the first ARC layer 139 is formed from HfO₂ having a thickness of about 60 A, the second ARC layer 141 is formed from Ta₂O₅ having a thickness of about 470 A, the first oxide layer 130 is a plasma enhanced oxide (PEOX) having a thickness of about 700 A, the metal layer 134 has a TiN layer 142 of about 300 A and a tungsten (W) layer of about 1600 A, the second oxide layer 132 is formed from an undoped silicon glass (USG) having a thickness of about 4000 A, the third oxide layer 135 is a low deposited rate resistor protection oxide (LRPO) having a thickness of about 250 A, the CESL has a thickness of about 375 A, and the fourth oxide layer 143 has a thickness of about 385 A.

The contact pad structure 120 is formed in a first cavity portion of the contact pad opening, which extends to the ILD layer 122 and does not terminate in an STI region of the substrate 112. As a result, the STI region is not needed in the PAD region 110, and a crystal defect due to Si dislocation in the STI region can be avoided.

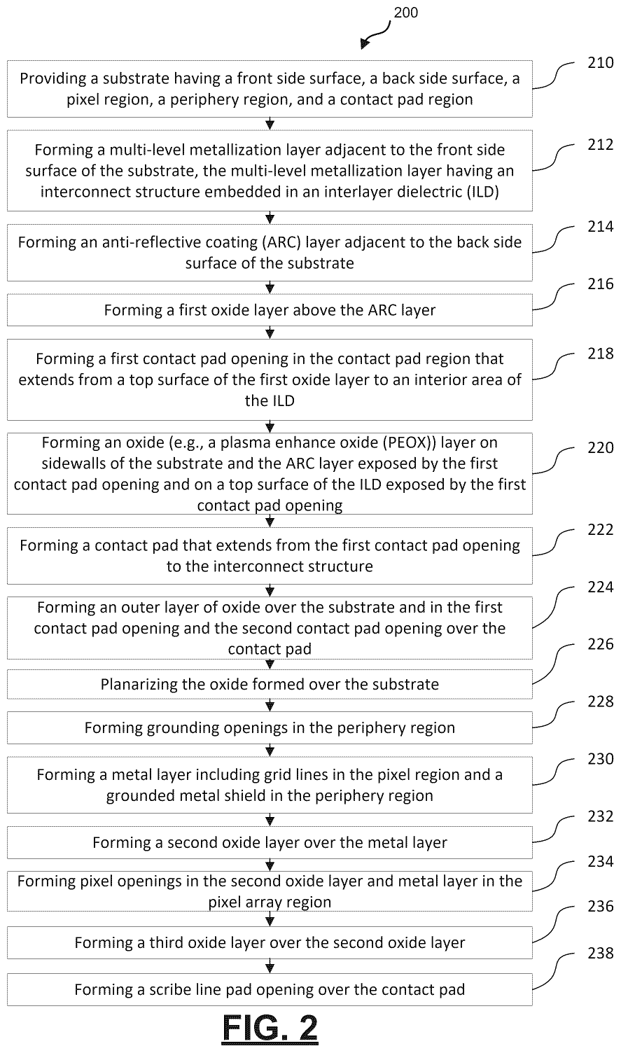

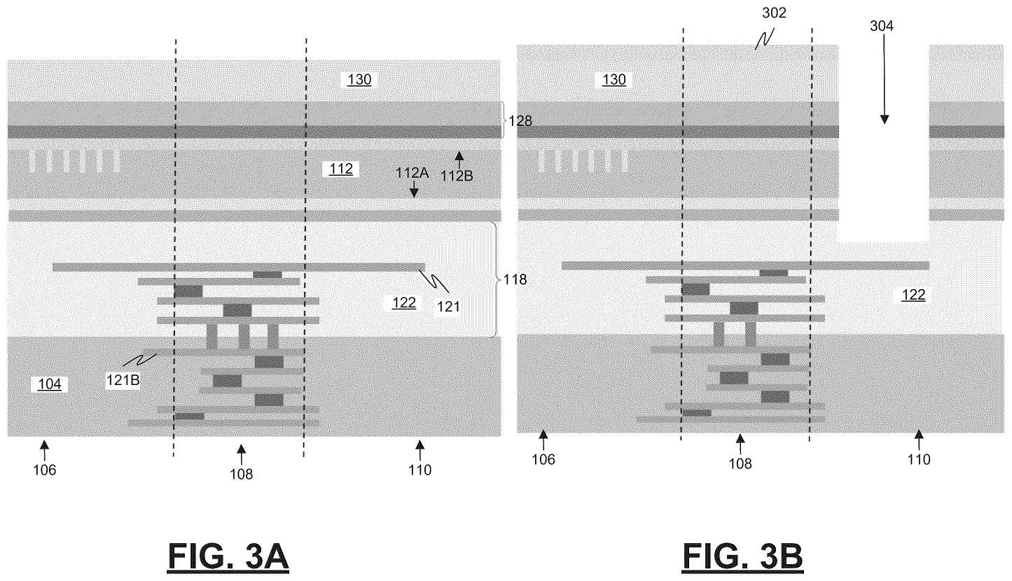

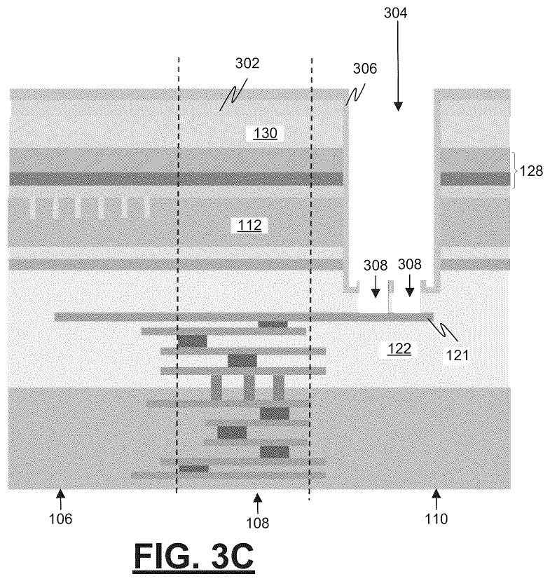

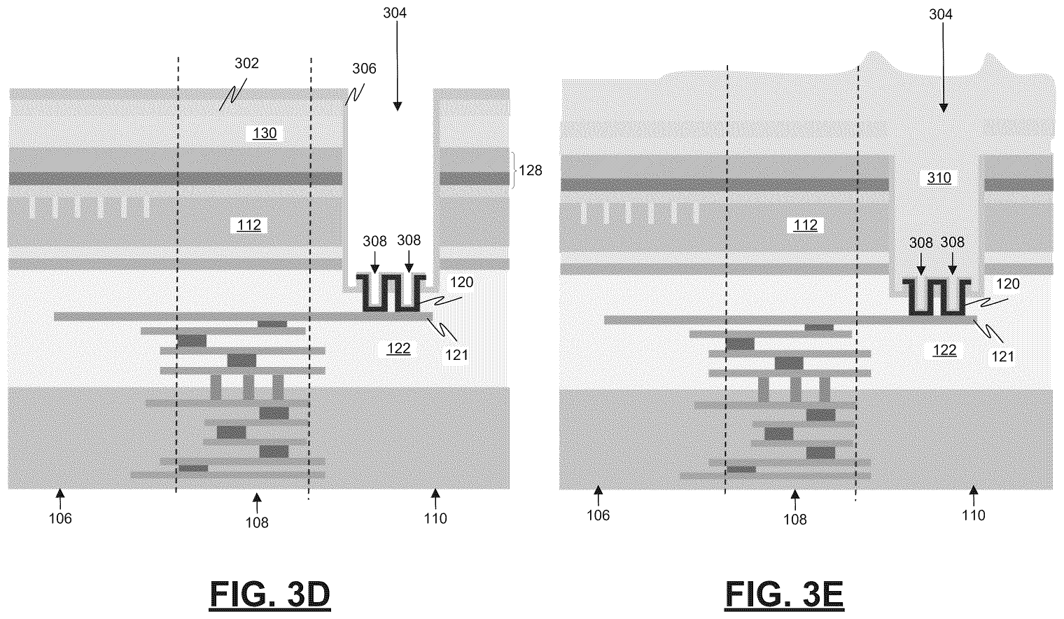

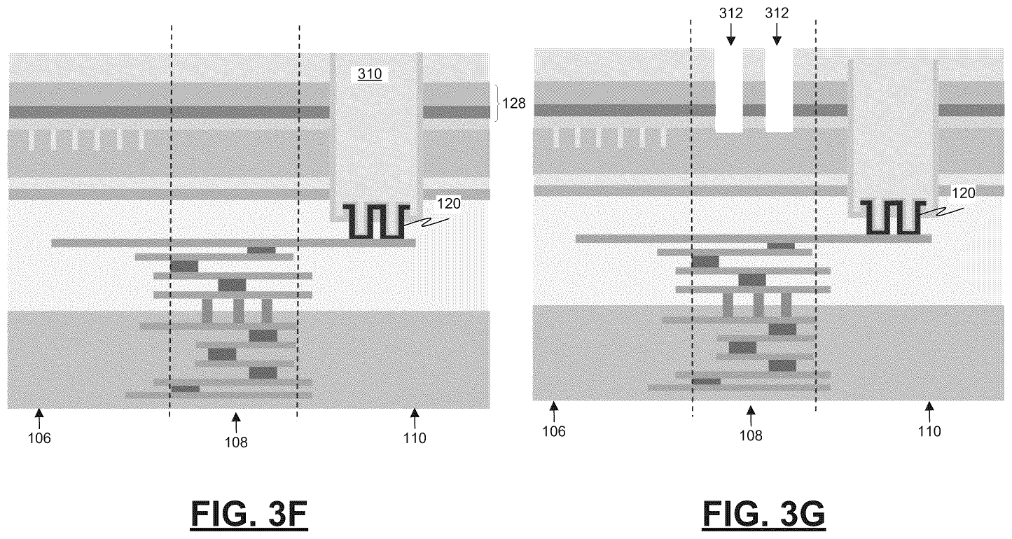

FIG. 2 is a flow diagram of an example method 200 for fabricating a CIS device, according to some embodiments. For illustrative purposes, the operations illustrated in FIG. 2 will be described with reference to FIGS. 3A-31, which shows cross-sectional views of a CIS device at various stages of its fabrication process, according to some embodiments. Operations can be performed in a different order or not performed depending on specific applications. It should be noted that method 200 may not produce a complete CIS device. Accordingly, it is understood that additional processes can be provided before, during, and after method, and that some other processes may only be briefly described herein. Elements in FIGS. 3A-31 with the same annotations as elements in FIG. 1 are described above. In some figures, some reference numbers of components or features illustrated therein may be omitted to avoid obscuring other components or features; this is for ease of depicting the figures.

The method 200 is merely an example, and is not intended to limit the present disclosure beyond what is explicitly recited in the claims. Additional steps may be provided before, during, and after example method 200, and some of the steps described can be moved, replaced, or eliminated for additional embodiments of example method 200. Additional features may be added in the semiconductor device depicted in the figures and some of the features described below can be replaced, modified, or eliminated in other embodiments of the semiconductor device.

It is understood that parts of the semiconductor device may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the operations of method 200, including any descriptions given with reference to the Figures are merely exemplary and are not intended to be limiting beyond what is specifically recited in the claims that follow.

At block 210, the method 200 includes providing a substrate having a front side surface, a back side surface, a pixel array region, a periphery region, and a contact pad region. Referring to the example of FIG. 3A, in an embodiment of block 210, a substrate 112 includes a front side surface 112A, a back side surface 112B, a pixel array region 106, a periphery region 108, and a contact pad region 110.

At block 212, the method 200 includes forming a multi-level metallization layer adjacent below the front side surface of the substrate, the multi-level metallization layer having an interconnect structure embedded in an interlayer dielectric (ILD) layer. The formation of multi-level metallization layer on the front side surface can be followed by bonding a carrier substrate such as an ASIC to the multi-level metallization layer. Referring to the example of FIG. 3A, in an embodiment of block 212, a multi-level metallization layer 118 is formed below the front side surface 112A of the substrate 112, the multi-level metallization layer 118 having an interconnect structure 121 embedded in an ILD layer 122. In the illustrated example, an interconnect structure 121B of an ASIC 104 is bonded to the interconnect structure 121 of the multi-level metallization layer 118.

At block 214, the method 200 includes forming an anti-reflective coating (ARC) layer above the back side surface of the substrate. Referring to the example of FIG. 3A, in an embodiment of block 214, an ARC layer 128 is formed above the back side surface 112B of the substrate 112.

At block 216, the method 200 includes forming a first oxide layer above the ARC layer. Referring to the example of FIG. 3A, in an embodiment of block 216, a first oxide layer 130 is formed above the ARC layer 128.

At block 218, the method 200 includes forming a first cavity portion of a contact pad opening in the contact pad region that extends from a top surface of the first oxide layer to an interior area of the ILD layer. In various embodiments, the first contact pad opening is formed by depositing a mask, patterning the mask with an opening, and etching the first cavity portion of a contact pad opening based on the patterned mask. In an embodiment, the mask is formed from silicon nitride (SiN) with a thickness of 880 A. Referring to the example of FIG. 3B, in an embodiment of block 218, a patterned mask 302 is formed above the first oxide layer 130, and a first cavity portion 304 of a contact pad opening is formed in the contact pad region 110 that extends from the patterned mask 302 and a top surface of the first oxide layer 130 to an interior area of the ILD layer 122.

Later, the contact pad structure 120 is formed in the first cavity portion 304 of a contact pad opening, which extends to the ILD layer 122 and does not terminate in an STI region of the substrate 112. As a result, the STI region is not needed and a crystal defect due to Si dislocation in the STI region can be avoided.

At block 220, the method 200 includes forming an oxide (e.g., a plasma enhance oxide (PEOX)) layer on sidewalls of the substrate and the ARC layer exposed by the first contact pad opening and on a top surface of the ILD layer exposed by the first contact pad opening. The forming an oxide layer on sidewalls of the substrate and the ARC layer exposed by the first contact pad opening and on a surface of the ILD layer exposed by the first contact pad opening may involve deposition of the oxide followed by etching the oxide. Referring to the example of FIG. 3C, in an embodiment of block 220, an oxide (e.g., a plasma enhance oxide (PEOX)) layer 306 is formed on sidewalls of the substrate 112 and the ARC layer 128 exposed by the first cavity portion 304 of a contact pad opening and on a surface of the ILD layer 122 exposed by the first cavity portion 304 of a contact pad opening.

At block 222, the method 200 includes forming a contact pad that extends from the first cavity portion of a contact pad opening to the interconnect structure. In various embodiments, forming a contact pad that extends from the first cavity portion of a contact pad opening to the interconnect structure includes forming a second cavity portion of a contact pad opening that extends from the oxide layer on the surface of the ILD layer exposed by the first cavity portion of a contact pad opening to the interconnect structure and forming the contact pad in the second cavity portion of a contact pad opening. In an embodiment, the contact pad is formed from aluminum copper (AlCu). In an embodiment, the AlCu contact pad is formed by deposition of an AlCu material layer and patterning and etching the AlCu material layer to form a pad structure. Referring to the example of FIG. 3C, in an embodiment of block 222, a second cavity portion 308 of a contact pad opening is formed that extends to the interconnect structure 121. Referring to the example of FIG. 3D, in an embodiment of block 222, a contact pad structure 120 is formed in the second cavity portion of a contact pad opening.

At block 224, the method 200 includes forming an outer layer of oxide over the substrate and in the first contact pad opening and the second contact pad opening over the contact pad. In various embodiments, forming an outer layer of oxide involves depositing an oxide layer using a PECVD process. Referring to the example of FIG. 3E, in an embodiment of block 224, an outer layer of oxide 310 is formed over the substrate 112 and in the first cavity portion 304 of a contact pad opening and the second cavity portion 308 of a contact pad opening over the contact pad structure 120.

At block 226, the method 200 includes planarizing the oxide formed over the substrate. In various embodiments planarizing the outer layer of oxide formed over the substrate includes removing oxide above the patterned mask, removing the patterned mask, and removing a portion of the oxide above the ARC layer using CMP operations. In various embodiments, etching operations are performed to remove oxide above the patterned mask, the patterned mask, and the portion of the oxide above the ARC layer followed by CMP operations to planarize the top surface of the oxide above the ARC layer. Referring to the example of FIG. 3F, in an embodiment of block 226, oxide above the patterned mask 302, the patterned mask 302, and a portion of the oxide above the ARC layer 128 have been removed. The oxide 310 above the ARC layer 128 has been planarized using CMP operations.

At block 228, the method 200 includes forming grounding openings in the periphery region. In various embodiments forming grounding openings in the periphery region involves etching operations. Referring to the example of FIG. 3G, in an embodiment of block 228, grounding openings 312 in the periphery region 108 have been formed.

At block 230, the method 200 includes forming a metal layer that includes grid lines in the pixel region and a grounded metal shield in the periphery region. In various embodiments the metal layer is formed by depositing a TiN layer over the pixel array region and the periphery region including in the grounding openings followed by depositing a tungsten (W) layer over the TIN layer. In various embodiments, forming the metal layer that includes grid lines in the pixel region and a grounded metal shield in the periphery region also includes depositing the TIN layer and the W layer over the PAD region when the TiN layer and the W layer are deposited over the pixel array region and the periphery region, wherein the portion of the TiN layer and the W layer that is deposited over the PAD region is removed in later operations.

At block 232, the method 200 includes forming a second oxide layer over the metal layer. In various embodiments the second oxide layer is formed via deposition. In various embodiments, forming the second oxide layer over the metal layer also includes forming the second oxide layer over the metal layer in the Pad region, wherein the portion of the second oxide layer that is formed over the PAD region is removed in later operations.

At block 234, the method 200 includes forming pixel openings in the second oxide layer, the metal layer, and a portion of the first oxide layer in the pixel array region thereby defining the grid lines. In various embodiments the pixel openings are formed via patterning and etching the metal layer. In various embodiments, forming pixel openings in the second oxide layer, the metal layer, and a portion of the first oxide layer in the pixel array region also includes removing the second oxide layer, the metal layer, and a portion of the first oxide layer over the PAD region.

Referring to the example of FIG. 3H, in an embodiment of blocks 230, 232, and 234, a metal layer 134 that includes grid lines 136 in the pixel array region 106 and a grounded metal shield 137 in the periphery region 108 has been formed. A second oxide layer 132 has been formed over the metal layer 134. Pixel openings 313 have been formed in the second oxide layer 132, the metal layer 134, and a portion of the first oxide layer 130 in the pixel array region 106. Also, the PAD region 110 does not have the metal layer 134 or the second oxide layer 132 formed above it.

At block 236, the method 200 includes forming a third oxide layer over the second oxide layer. In various embodiments, forming the third oxide layer includes depositing polyethylene oxide (PEOX) using a CVD process. In various embodiments, forming the third oxide layer includes depositing the third oxide layer over the second oxide layer above the pixel array region and the periphery region, and depositing the third oxide layer over the first oxide layer above the PAD region.

At block 238, the method 200 includes forming a scribe line pad opening over the contact pad. Referring to the example of FIG. 3I, in an embodiment of blocks 236 and 238, a third oxide layer 135 is formed over the second oxide layer 132 and a scribe line pad opening 314 is formed over the contact pad structure 120.

The aspect ratio of the scribe line pad opening 314 is much higher than the aspect ratio of a scribe line pad opening formed by a process that terminates a first contact pad opening in an STI region of a substrate. Because of the aspect ratio of the scribe line pad opening 314, an anisotropic etching technique may be employed to etch the scribe line pad opening 314.

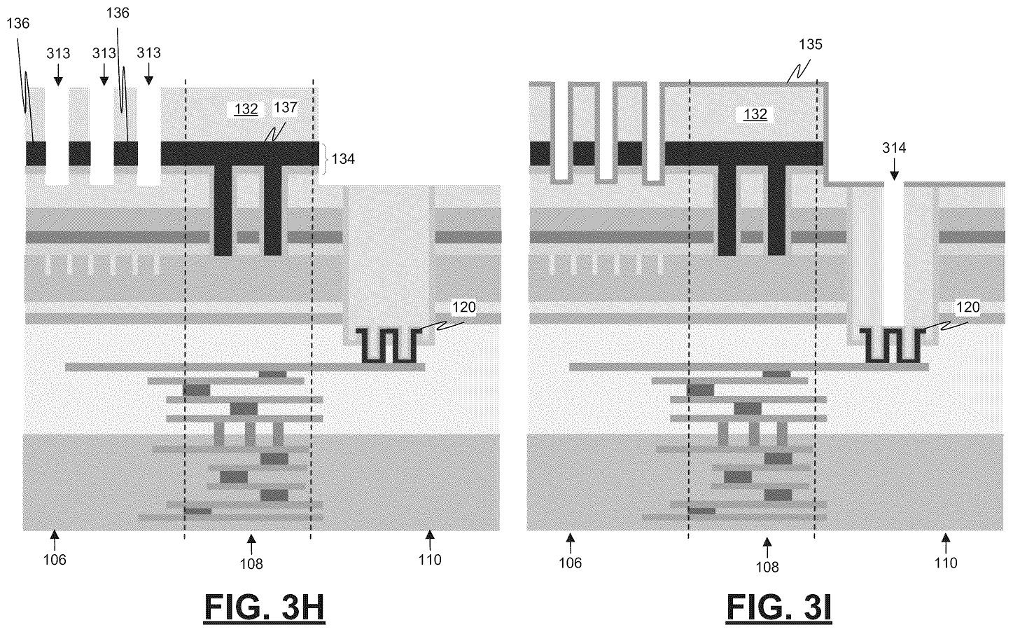

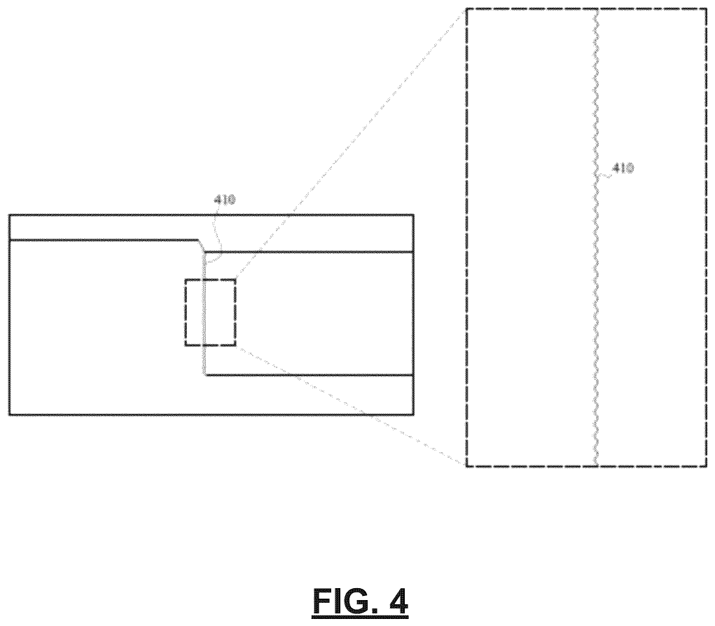

FIG. 4 is a cross-sectional schematic diagram that illustrates an example anisotropic etching wall that can be achieved for the scribe line pad opening 314. In this example, a technique such as a Bosch plasma etching process—a high-aspect ratio plasma etching process—has been employed. The Bosch plasma etching process can be used to etch a straight wall 410. The Bosch plasma etching process includes cyclic process involving isotropic etching followed by a protection film deposition using quick gas switching in a plasma etching chamber. The isotropic etching may involve Deep Reactive Ion Etching (DRIE), depositing a protective coating on etched areas, and quickly switching between etch and deposition steps during the manufacturing process, thereby carving (etching) a small section of an opening and layering (depositing) material on walls of the opening to protect the walls during further etching steps.

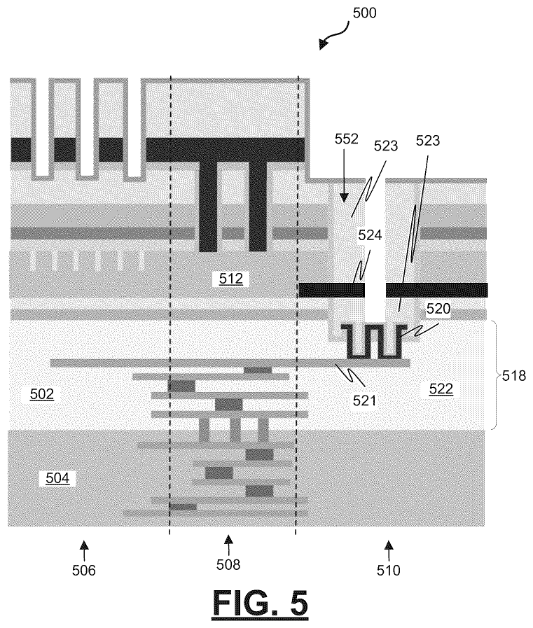

Although the foregoing examples were illustrated with respect to the formation of a BSI image sensor without STI in the substrate in the PAD region, the foregoing apparatus, devices, and methods may also be used in connection with the formation of a BSI image sensor with STI in the substrate in the PAD region. For example, FIG. 5 depicts a schematic cross-sectional view of an example portion of an example CIS device 500. The example CIS device 500 includes a CIS system-on-a-chip (SOC) 502 and a carrier substrate, such as an application specific integrated circuit (ASIC) 504. The example CIS device 500 has a plurality of regions including a pixel array region 506, a periphery region 508 (such as a black level correction (BLC) region) laterally surrounding the pixel array region 506, and a contact pad (PAD) region 510. The example CIS device 500 may further include other regions.

The example CIS SOC 502 includes a substrate 512, a multi-level metallization layer 518, and a pad structure 520 disposed within the PAD region 510. The substrate 512 includes an STI region 524 in the PAD region 510. The pad structure 520 includes a conductive layer that is electrically coupled to an interconnect structure 521 of the multi-level metallization layer 518, which is embedded in an ILD layer 522 of the multi-level metallization layer 518.

The interconnect structure 521 provides routing and electrical connections between device elements formed in and/or over the substrate 512. The interconnect structure 521 may include one or more conductive features, which in this example include metal lines and/or vias formed therein in multi-level metallization layer 518. The conductive features may be electrically connected to active and/or passive devices of the substrate 512 by contacts (not shown in the figures). In some embodiments, the interconnect structure 521 may be formed using a single and/or a dual damascene process, a VIA-first process, or a metal-first process.

The contact pad structure 520 is formed in a first cavity portion 552 of a contact pad opening (e.g., with an oxide layer 523 and a portion of the STI region 524 disposed above the contact pad structure 520 in the first cavity portion 552), which extends to the ILD layer 522 and does not terminate in the STI region of the substrate 512. As a result, a crystal defect due to Si dislocation in the STI region can be avoided.

A scribe line pad opening 514 is formed over the contact pad structure 520. The aspect ratio of the scribe line pad opening 514 is much higher than the aspect ratio of a scribe line pad opening formed by a process that terminates a first contact pad opening in an STI region of a substrate. Because of the aspect ratio of the scribe line pad opening 514, an anisotropic etching technique may be employed to etch the scribe line pad opening 514.

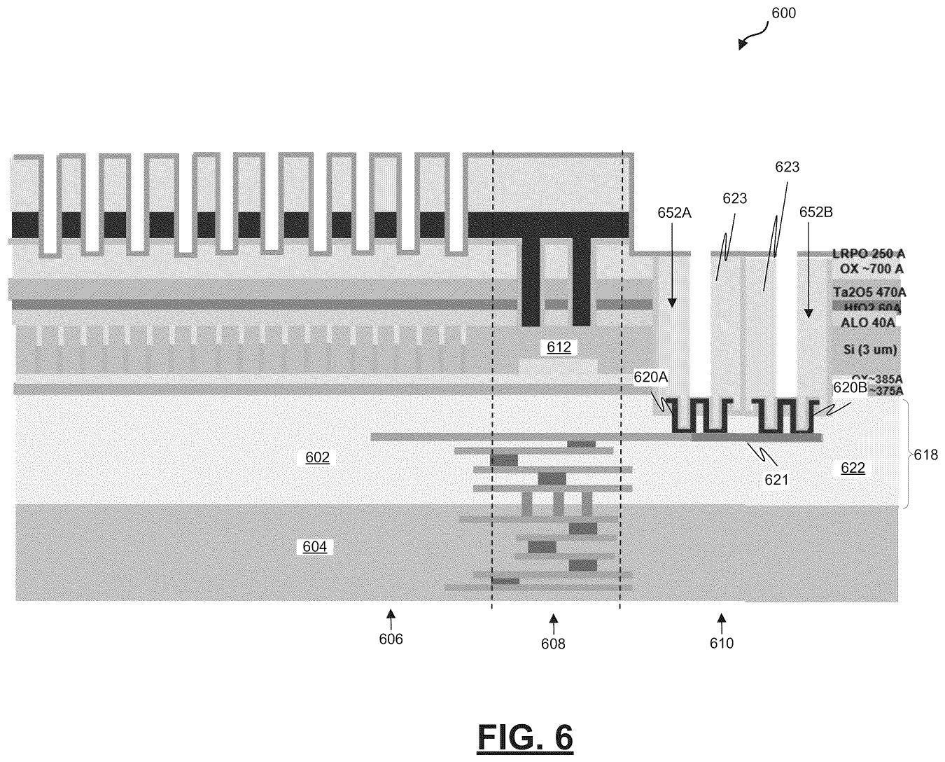

In accordance with another embodiment, the apparatus, devices, and methods described herein may also be used in connection with the formation of a BSI image sensor with a first cavity portion for each of a plurality of a contact pad openings that extends to an ILD layer and that does not terminate in an STI region of a substrate. FIG. 6 depicts a schematic cross-sectional view of an example portion of an example CIS device 600. The example CIS device 600 includes a CIS system-on-a-chip (SOC) 602 and a carrier substrate, such as an application specific integrated circuit (ASIC) 604. The example CIS device 600 has a plurality of regions including a pixel array region 606, a periphery region 608 (such as a black level correction (BLC) region) laterally surrounding the pixel array region 606, and a contact pad (PAD) region 610. The example CIS device 600 may further include other regions.

The example CIS SOC 602 includes a substrate 612, a multi-level metallization layer 618, and a plurality of pad structures 620A and 620B disposed within the PAD region 610. The pad structures 620A and 620B each include a conductive layer that is electrically coupled to an interconnect structure 621 of the multi-level metallization layer 618, which is embedded in an ILD layer 622 of the multi-level metallization layer 618.

A first contact pad structure 620A is formed in a first cavity portion 652A of a first contact pad opening (e.g., with an oxide layer 623 disposed above the first contact pad structure 620A in the first cavity portion 652A), which extends to the ILD layer 622 and does not terminate in an STI region of the substrate 612. Similarly, a second contact pad structure 620B is formed in a first cavity portion 652B of a second contact pad opening (e.g., with the oxide layer 623 disposed above the second contact pad structure 620B in the first cavity portion 652B), which extends to the ILD layer 622 and does not terminate in an STI region of the substrate 612. As a result, the STI region is not needed and a crystal defect due to Si dislocation in the STI region can be avoided.

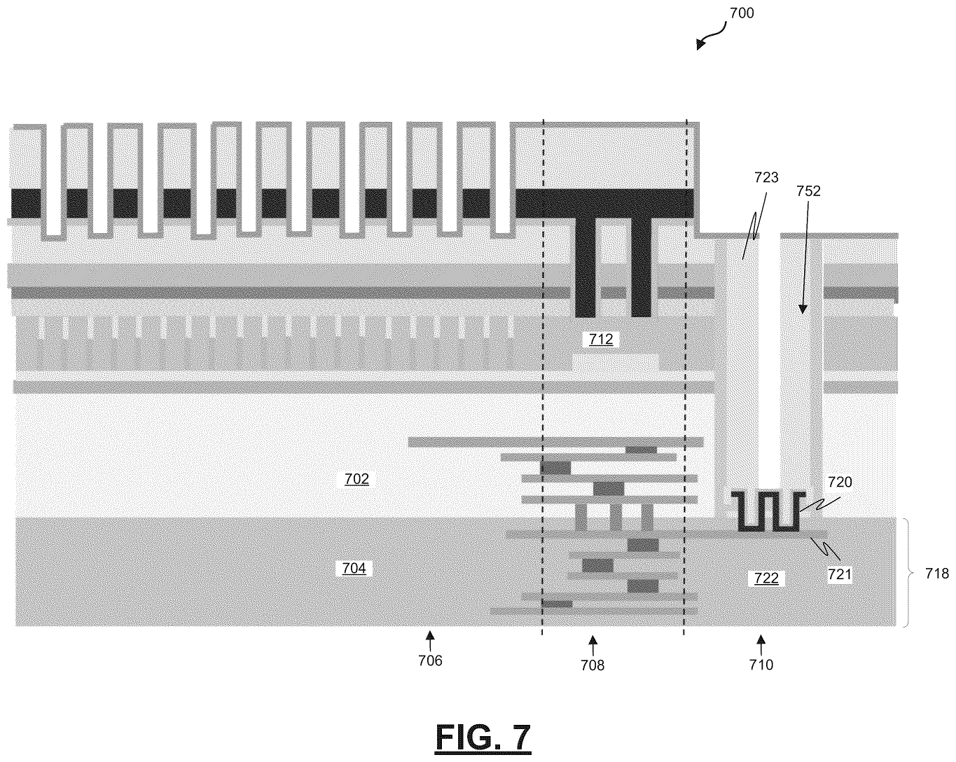

In accordance with another embodiment, the apparatus, devices, and methods described herein may also be used in connection with the formation of a BSI image sensor with a first cavity portion for a contact pad opening that extends to an ILD layer of a carrier substrate, such as an ASIC, and that does not terminate in an STI region of a substrate. FIG. 7 depicts a schematic cross-sectional view of an example portion of an example CIS device 700. The example CIS device 700 includes a CIS system-on-a-chip (SOC) 702 and a carrier substrate, such as an application specific integrated circuit (ASIC) 704. The example CIS device 700 has a plurality of regions including a pixel array region 706, a periphery region 708 (such as a black level correction (BLC) region) laterally surrounding the pixel array region 706, and a contact pad (PAD) region 710. The example CIS device 700 may further include other regions.

The example CIS SOC 702 includes a substrate 712. The example ASIC 704 includes a multi-level metallization layer 718, and a pad structure 720 disposed within the PAD region 710. The pad structure 720 includes a conductive layer that is electrically coupled to an interconnect structure 721 of the multi-level metallization layer 718, which is embedded in an ILD layer 722 of the multi-level metallization layer 718.

The contact pad structure 720 is formed in a first cavity portion 752 of a contact pad opening (e.g., with an oxide layer 723 disposed above the contact pad structure 720 in the first cavity portion 752), which extends through the CIS SOC 702 to the ILD layer 722 and does not terminate in an STI region of the substrate 712. As a result, the STI region is not needed and a crystal defect due to Si dislocation in the STI region can be avoided.

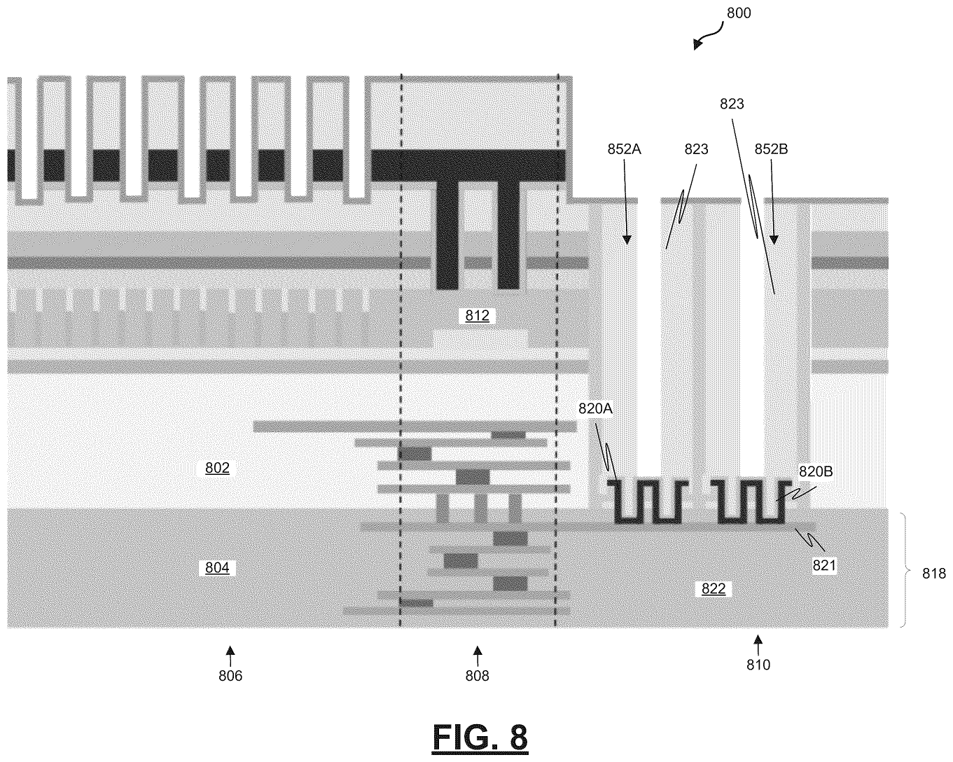

Other configurations are also contemplated wherein a contact pad structure is formed in a first cavity portion of a contact pad opening that extends to an ILD layer and does not terminate in an STI region of a substrate. For example, FIG. 8 depicts a schematic cross-sectional view of an example portion of an example CIS device 800. The example CIS device 800 includes a CIS system-on-a-chip (SOC) 802 and a carrier substrate, such as an application specific integrated circuit (ASIC) 804. The example CIS device 800 has a plurality of regions including a pixel array region 806, a periphery region 808 (such as a black level correction (BLC) region) laterally surrounding the pixel array region 806, and a contact pad (PAD) region 810. The example CIS device 800 may further include other regions. The example CIS SOC 802 includes a substrate 812. The example ASIC 804 includes a multi-level metallization layer 818, and pad structures 820A and 820B disposed within the PAD region 810. The pad structures 820A and 820B include a conductive layer that is electrically coupled to an interconnect structure 821 of the multi-level metallization layer 818, which is embedded in an ILD layer 822 of the multi-level metallization layer 818. In this example, the first contact pad structure 820A is formed in a first cavity portion 852A of a first contact pad opening (e.g., with an oxide layer 823 disposed above the contact pad structure 820A in the first cavity portion 852A) that extends through the CIS SOC 802 to the ILD layer 822 and does not terminate in an STI region of the substrate 812. Also, the second contact pad structure 820B is formed in a first cavity portion 852B of a second contact pad opening (e.g., with an oxide layer 823 disposed above the contact pad structure 820A in the first cavity portion 852B) that extends through the CIS SOC 802 to the ILD layer 822 and does not terminate in an STI region of the substrate. As a result, the STI region is not needed and a crystal defect due to Si dislocation in the STI region can be avoided.

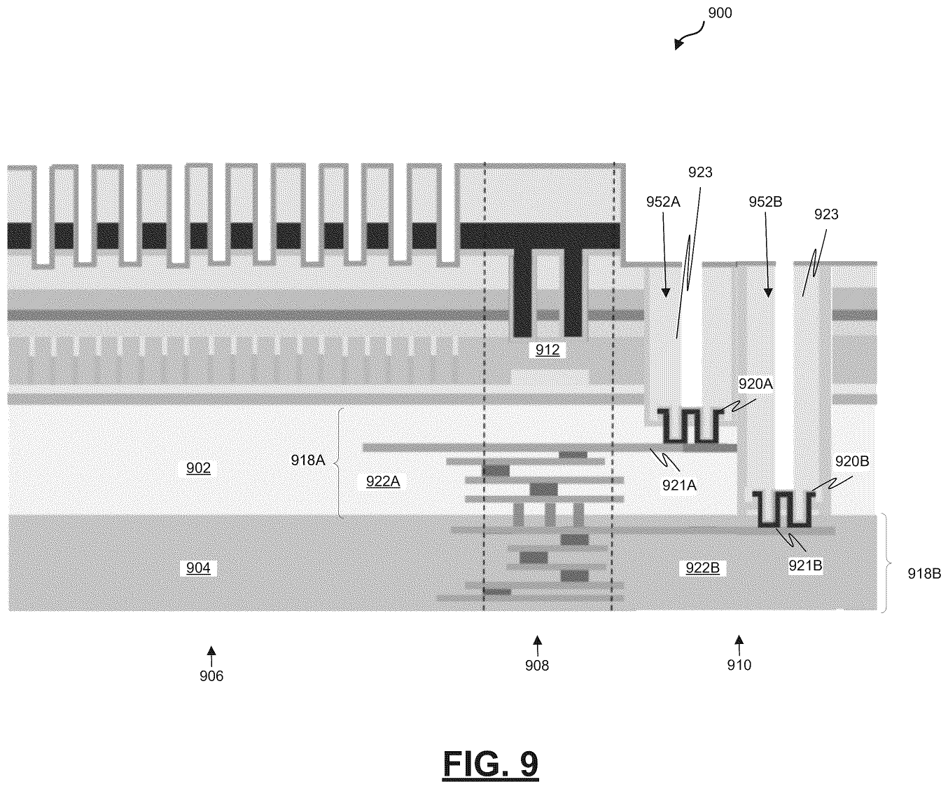

In another example, FIG. 9 depicts a schematic cross-sectional view of an example portion of another example CIS device 900. The example CIS device 900 includes a CIS system-on-a-chip (SOC) 902 and a carrier substrate, such as an application specific integrated circuit (ASIC) 904. The example CIS device 900 has a plurality of regions including a pixel array region 906, a periphery region 908 (such as a black level correction (BLC) region) laterally surrounding the pixel array region 906, and a contact pad (PAD) region 910. The example CIS device 900 may further include other regions. The example CIS SOC 902 includes a substrate 912. The example CIS SOC 902 includes a multi-level metallization layer 918A and the example ASIC 904 includes a multi-level metallization layer 918B. Pad structures 920A and 920B are disposed within the PAD region 910. The pad structure 920A includes a conductive layer that is electrically coupled to an interconnect structure 921A of the multi-level metallization layer 918A which is embedded in an ILD layer 922A of the multi-level metallization layer 918A, and the pad structure 920B includes a conductive layer that is electrically coupled to an interconnect structure 921B of the multi-level metallization layer 918B which is embedded in an ILD layer 922B of the multi-level metallization layer 918B. In this example, a first contact pad structure 920A may be formed in a first cavity portion 952A of a first contact pad opening (e.g., with an oxide layer 923 disposed above the contact pad structure 920A in the first cavity portion 952A) that extends to the ILD layer 922A and does not terminate in an STI region of the substrate 912, and a second contact pad structure 920B may be formed in a first cavity portion 952B of a second contact pad opening (e.g., with an oxide layer 923 disposed above the contact pad structure 920B in the first cavity portion 952B) that extends through the CIS SOC 902 to the ILD layer 922B and does not terminate in an STI region of the substrate 912. As a result, an STI region is not needed and a crystal defect due to Si dislocation in the STI region can be avoided.

In some aspects, the techniques described herein relate to a fabrication method, including: providing a substrate having a front side surface, a back side surface, and a contact pad region; providing an interconnect structure embedded in an interlayer dielectric (ILD) layer below the front side surface of the substrate; forming a first cavity portion of a contact pad opening in the contact pad region that extends from above the back side surface through the substrate to an interior area of the ILD layer below the front side surface; forming a contact pad that extends from the first cavity portion of the contact pad opening to the interconnect structure; forming an oxide layer over the contact pad; and forming a scribe line pad opening through the oxide layer to the contact pad.

In some aspects, the techniques described herein relate to a fabrication method, wherein providing an interconnect structure embedded in an ILD layer includes forming a multi-level metallization layer below the front side surface of the substrate, the multi-level metallization layer including the interconnect structure and the ILD layer.

In some aspects, the techniques described herein relate to a fabrication method, further including bonding an application specific integrated circuit (ASIC) to a multi-level metallization layer formed below the front side surface, and wherein the interconnect structure and the ILD layer are embedded in the ASIC.

In some aspects, the techniques described herein relate to a fabrication method, further including forming an anti-reflective coating (ARC) layer above the back side surface of the substrate, and forming a first oxide layer above the ARC layer, and wherein: forming the first cavity portion of the contact pad opening includes forming the first cavity portion of the contact pad opening to extend from a top surface of the first oxide layer to the interior area of the ILD layer.

In some aspects, the techniques described herein relate to a fabrication method, further including forming the oxide layer on: sidewall portions of the substrate exposed by the first cavity portion of the contact pad opening, sidewall portions of the ARC layer exposed by the first cavity portion of the contact pad opening, and a surface of the ILD layer exposed by the first cavity portion of the contact pad opening.

In some aspects, the techniques described herein relate to a fabrication method, wherein forming the contact pad includes: forming a second cavity portion of the contact pad opening that extends from the oxide layer on the surface of the ILD layer exposed by the first cavity portion of the contact pad opening to the interconnect structure; and forming the contact pad in the second cavity portion of the contact pad opening.

In some aspects, the techniques described herein relate to a fabrication method, wherein forming a scribe line pad opening through the oxide layer to the contact pad includes performing anisotropic etching operations to form the scribe line pad opening.

In some aspects, the techniques described herein relate to a fabrication method, wherein performing anisotropic etching operations includes performing a cyclic process involving isotropic etching followed by a protection film deposition.

In some aspects, the techniques described herein relate to a semiconductor device, including: a substrate having a front side surface, a back side surface, and a contact pad region; an interconnect structure embedded in an interlayer dielectric (ILD) layer below the front side surface of the substrate; an application specific integrated circuit (ASIC) bonded to a multi-level metallization layer formed below the front side surface; a first contact pad opening in the contact pad region that extends from above the back side surface through the substrate to an interior area of the ILD layer below the front side surface; a contact pad that extends from the first contact pad opening to the interconnect structure; an oxide layer formed over the contact pad; and a scribe line pad opening formed through the oxide layer to the contact pad.

In some aspects, the techniques described herein relate to a semiconductor device, wherein the multi-level metallization layer includes the interconnect structure and the ILD layer.

In some aspects, the techniques described herein relate to a semiconductor device, wherein the interconnect structure and the ILD layer are embedded in the ASIC.

In some aspects, the techniques described herein relate to a semiconductor device, wherein the contact pad includes aluminum copper (AlCu).

In some aspects, the techniques described herein relate to a semiconductor device, further including: a second contact pad opening in the contact pad region that extends from above the back side surface through the substrate to an interior area of the ILD layer below the front side surface; a second contact pad that extends from the second contact pad opening to the interconnect structure, wherein the oxide layer is formed over the contact pad; and a second scribe line pad opening formed through the oxide layer to the contact pad.

In some aspects, the techniques described herein relate to a semiconductor device, further including: an anti-reflective coating (ARC) layer above the back side surface of the substrate; and a first oxide layer above the ARC layer, wherein the first contact pad opening extends from a top surface of the first oxide layer to the interior area of the ILD layer.

In some aspects, the techniques described herein relate to a fabrication method, including: providing a semiconductor structure having a plurality of regions including a contact pad region, the semiconductor structure including a substrate having a shallow trench isolation (STI) region in the contact pad region and a multi-level metallization layer with an interconnect structure embedded in an interlayer dielectric (ILD) layer; forming a first contact pad opening in the contact pad region that extends through the STI region to an interior area of the ILD, wherein the first contact pad opening does not terminate in the STI region; forming a contact pad that extends from the first contact pad opening to the interconnect structure; forming an oxide layer over the contact pad; and forming a scribe line pad opening through the oxide layer to the contact pad.

In some aspects, the techniques described herein relate to a fabrication method, further including forming an anti-reflective coating (ARC) layer above a back side surface of the substrate, and forming a first oxide layer above the ARC layer, and wherein: forming the first contact pad opening includes forming the first contact pad opening to extend from a top surface of the first oxide layer to an interior area of the ILD layer.

In some aspects, the techniques described herein relate to a fabrication method, further including forming the oxide layer on: sidewall portions of the substrate exposed by the first contact pad opening, sidewall portions of the ARC layer exposed by the first contact pad opening, and a surface of the ILD layer exposed by the first contact pad opening.

In some aspects, the techniques described herein relate to a fabrication method, wherein forming the contact pad includes: forming a second cavity portion of the first contact pad opening that extends from the oxide layer on the surface of the ILD layer exposed by the first contact pad opening to the interconnect structure; and forming the contact pad in the second cavity portion of the first contact pad opening.

In some aspects, the techniques described herein relate to a fabrication method, wherein forming the scribe line pad opening through the oxide layer to the contact pad includes performing anisotropic etching operations to form the scribe line pad opening.

In some aspects, the techniques described herein relate to a fabrication method, wherein performing anisotropic etching operations includes performing a cyclic process involving isotropic etching followed by a protection film deposition.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A fabrication method, comprising:
providing a substrate having a front side surface, a back side surface, and a contact pad region;
providing an interconnect structure embedded in an interlayer dielectric (ILD) layer below the front side surface of the substrate;
forming a first cavity portion of a contact pad opening in the contact pad region that extends from above the back side surface through the substrate to an interior area of the ILD layer below the front side surface;
forming a contact pad that extends from the first cavity portion of the contact pad opening to the interconnect structure;
forming an oxide layer over the contact pad; and
forming a scribe line pad opening through the oxide layer to the contact pad.

2. The fabrication method of claim 1, wherein providing an interconnect structure embedded in an ILD layer comprises forming a multi-level metallization layer below the front side surface of the substrate, the multi-level metallization layer including the interconnect structure and the ILD layer.

3. The fabrication method of claim 1, further comprising bonding an application specific integrated circuit (ASIC) to a multi-level metallization layer formed below the front side surface, and wherein the interconnect structure and the ILD layer are embedded in the ASIC.

4. The fabrication method of claim 1, further comprising forming an anti-reflective coating (ARC) layer above the back side surface of the substrate, and forming a first oxide layer above the ARC layer, and wherein:
forming the first cavity portion of the contact pad opening comprises forming the first cavity portion of the contact pad opening to extend from a top surface of the first oxide layer to the interior area of the ILD layer.

5. The fabrication method of claim 4, further comprising forming the oxide layer on: sidewall portions of the substrate exposed by the first cavity portion of the contact pad opening, sidewall portions of the ARC layer exposed by the first cavity portion of the contact pad opening, and a surface of the ILD layer exposed by the first cavity portion of the contact pad opening.

6. The fabrication method of claim 5, wherein forming the contact pad comprises:
forming a second cavity portion of the contact pad opening that extends from the oxide layer on the surface of the ILD layer exposed by the first cavity portion of the contact pad opening to the interconnect structure; and
forming the contact pad in the second cavity portion of the contact pad opening.

7. The fabrication method of claim 1, wherein forming the scribe line pad opening through the oxide layer to the contact pad comprises performing anisotropic etching operations to form the scribe line pad opening.

8. The fabrication method of claim 7, wherein performing anisotropic etching operations comprises performing a cyclic process involving isotropic etching followed by a protection film deposition.

9. A semiconductor device, comprising:
a substrate having a front side surface, a back side surface, and a contact pad region;
an interconnect structure embedded in an interlayer dielectric (ILD) layer below the front side surface of the substrate;
an application specific integrated circuit (ASIC) bonded to a multi-level metallization layer formed below the front side surface;
a first contact pad opening in the contact pad region that extends from above the back side surface through the substrate to an interior area of the ILD layer below the front side surface;
a contact pad that extends from the first contact pad opening to the interconnect structure;
an oxide layer formed over the contact pad; and
a scribe line pad opening formed through the oxide layer to the contact pad.

10. The semiconductor device of claim 9, wherein the multi-level metallization layer includes the interconnect structure and the ILD layer.

11. The semiconductor device of claim 9, wherein the interconnect structure and the ILD layer are embedded in the ASIC.

12. The semiconductor device of claim 9, wherein the contact pad comprises aluminum copper (AlCu).

13. The semiconductor device of claim 9, further comprising:
a second contact pad opening in the contact pad region that extends from above the back side surface through the substrate to an interior area of the ILD layer below the front side surface;
a second contact pad that extends from the second contact pad opening to the interconnect structure, wherein the oxide layer is formed over the contact pad; and
a second scribe line pad opening formed through the oxide layer to the contact pad.

14. The semiconductor device of claim 9, further comprising:
an anti-reflective coating (ARC) layer above the back side surface of the substrate; and
a first oxide layer above the ARC layer, wherein the first contact pad opening extends from a top surface of the first oxide layer to the interior area of the ILD layer.

15. A fabrication method, comprising:
providing a semiconductor structure having a plurality of regions including a contact pad region, the semiconductor structure comprising a substrate having a shallow trench isolation (STI) region in the contact pad region and a multi-level metallization layer with an interconnect structure embedded in an interlayer dielectric (ILD) layer;
forming a first contact pad opening in the contact pad region that extends through the STI region to an interior area of the ILD, wherein the first contact pad opening does not terminate in the STI region;
forming a contact pad that extends from the first contact pad opening to the interconnect structure;
forming an oxide layer over the contact pad; and
forming a scribe line pad opening through the oxide layer to the contact pad.

16. The fabrication method of claim 15, further comprising forming an anti-reflective coating (ARC) layer above a back side surface of the substrate, and forming a first oxide layer above the ARC layer, and wherein:
forming the first contact pad opening comprises forming the first contact pad opening to extend from a top surface of the first oxide layer to an interior area of the ILD layer.

17. The fabrication method of claim 16, further comprising forming the oxide layer on: sidewall portions of the substrate exposed by the first contact pad opening, sidewall portions of the ARC layer exposed by the first contact pad opening, and a surface of the ILD layer exposed by the first contact pad opening.

18. The fabrication method of claim 17, wherein forming the contact pad comprises:
forming a second cavity portion of the first contact pad opening that extends from the oxide layer on the surface of the ILD layer exposed by the first contact pad opening to the interconnect structure; and
forming the contact pad in the second cavity portion of the first contact pad opening.

19. The fabrication method of claim 15, wherein forming the scribe line pad opening through the oxide layer to the contact pad comprises performing anisotropic etching operations to form the scribe line pad opening.

20. The fabrication method of claim 19, wherein performing anisotropic etching operations comprises performing a cyclic process involving isotropic etching followed by a protection film deposition.
